(19) United States
(12) Patent Application Publication
(10) Pub. No.: US 2026/0202040 A1
(43) Pub. Date: Jul. 16, 2026

(54) DECORATIVE PANEL AND MANUFACTURING METHOD

(71) Applicant: ALPS ALPINE CO., LTD., Tokyo (JP)

(72) Inventors: Hiroshi IKEHARA, Fukushima (JP); Satoru TAKEMORI, Fukushima (JP); Takeaki MAEHATA, Fukushima (JP)

(21) Appl. No.: 19/459,455

(22) Filed: Jan. 26, 2026

Related U.S. Application Data
(63) Continuation of application No. PCT/JP2024/008773, filed on Mar. 7, 2024.

(30) Foreign Application Priority Data
Jul. 27, 2023 (JP) 2023-122396

(51) Int. Cl. F21V 11/00; H10H 29/855

(52) U.S. Cl. CPC F21V 11/00; H10H 29/8552

(57) ABSTRACT

A decorative panel includes a transparent resin layer, a light-transmissive substrate configured to be disposed on a back side of the transparent resin layer and configured to visually express a three-dimensional pattern created by an uneven surface of the light-transmissive substrate, and a semi-transmissive layer configured to be disposed on a back side of the light-transmissive substrate and having a contour corresponding to the uneven surface of the light-transmissive substrate.

### CROSS-REFERENCE TO RELATED APPLICATIONS

This application is a continuation application of International Application No. PCT/JP2024/008773 filed on Mar. 7, 2024, and designated the U.S., which is based upon and claims priority to Japanese Patent Application No. 2023-122396 filed on Jul. 27, 2023, the entire contents of which are incorporated herein by reference.

### BACKGROUND

### 1. Technical Field

The present invention relates to a decorative panel and a manufacturing method.

### 2. Description of Related Art

Japanese Patent No. 6899969 (hereinafter “Patent Document 1”) discloses a decorative sheet having a decorative layer and a light-shielding layer, and capable of displaying an optical image of a predetermined shape on a surface by partially causing light emitted from an LED to be transmitted through the light-shielding layer.

Patent Document 1 discloses a technique in which the decorative sheet is provided with an intermediate color tone layer arranged between the decorative layer and the light-shielding layer, so that the outline of the light-transmissive portion of the light-shielding layer lower than the intermediate color tone layer is inconspicuous when an optical image is not displayed.

Japanese Patent No. 6405004 (hereinafter “Patent Document 2”) discloses a decorative sheet in which light-reflective projecting portions are formed on a sheet-like or plate-like light-transmissive substrate, thereby obtaining a design effect unique to the light-reflective projecting portions.

### SUMMARY

A decorative panel according to an embodiment includes a transparent resin layer, a light-transmissive substrate configured to be disposed on a back side of the transparent resin layer and configured to visually express a three-dimensional pattern created by an uneven surface of the light-transmissive substrate, and a semi-transmissive layer configured to be disposed on a back side of the light-transmissive substrate and having a contour corresponding to the uneven surface of the light-transmissive substrate.

### BRIEF DESCRIPTION OF THE DRAWINGS

FIG. 1 is a diagram schematically illustrating a laminate structure of a decorative panel according to an embodiment;

FIG. 2A is a plan view of the decorative panel illustrated in FIG. 1;

FIG. 2B is a plan view of the decorative panel illustrated in FIG. 1;

FIG. 3 is a flowchart showing an example of a procedure of a method of manufacturing the decorative panel according to the embodiment;

FIG. 4 is a diagram schematically illustrating a laminate structure of a conventional decorative sheet;

FIG. 5A is a diagram illustrating a display example of a three-dimensional pattern and a graphic symbol on the conventional decorative sheet;

FIG. 5B is a diagram illustrating a display example of a three-dimensional pattern and a graphic symbol on the conventional decorative sheet;

FIG. 6A is a diagram illustrating a display example of a three-dimensional pattern and a graphic symbol on the decorative panel according to the embodiment; and

FIG. 6B is a diagram illustrating a display example of a three-dimensional pattern and a graphic symbol on the decorative panel according to the embodiment.

### DETAILED DESCRIPTION

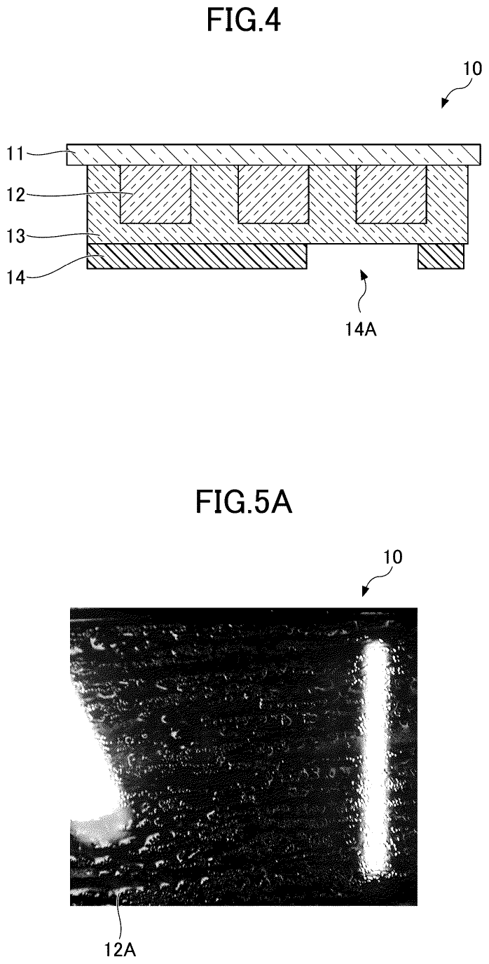

However, as illustrated in FIG. 4, in the case where the decorative sheet of Patent Document 2 is provided with a semi-transmissive layer and configured in such a manner that an optical image is visible from the front surface side when the back surface is irradiated with light, and an outer frame of the optical image is not visible from the front surface side when the back surface is not irradiated with light, uneven illumination of the optical image may occur. This is because the thickness of the semi-transmissive layer is different between the region having the light-reflective projecting portions and the region not having the light-reflective projecting portions.

According to a decorative panel according to an embodiment, a three-dimensional pattern is visible from the front side, and uneven illumination of a graphic symbol can be suppressed.

Hereinafter, an embodiment will be described with reference to the drawings.

### Configuration of Decorative Panel 100

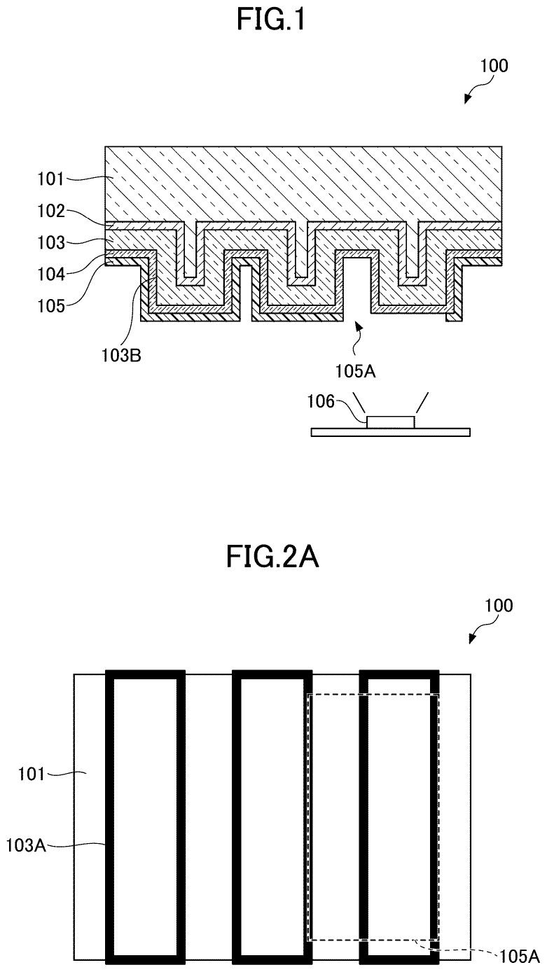

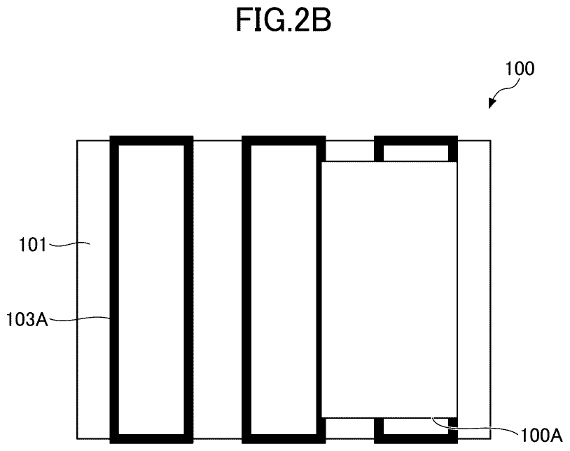

FIG. 1 is a diagram schematically illustrating a laminate structure of a decorative panel 100 according to the embodiment. FIGS. 2A and 2B are plan views of the decorative panel 100 illustrated in FIG. 1.

The decorative panel 100 illustrated in FIG. 1 is a panel-shaped component having a decorative pattern (for example, grain pattern, metal pattern, leather pattern, etc.) on a smooth front surface. When the decorative panel 100 is installed at a discretionarily chosen place (e.g., the interior of an automobile), the decorative flat surface can be formed at the installation place.

As illustrated in FIG. 1, the decorative panel 100 includes a transparent resin layer 101, a binder layer 102, a light-transmissive substrate 103, a semi-transmissive layer 104, a light-shielding layer 105, and a light source 106 in this order from the front side (upper side in the drawing).

The transparent resin layer 101 is superposed on the front surface of the binder layer 102. The transparent resin layer 101 is a transparent resin member in the form of a flat plate, and is disposed as the outermost layer that constitutes the front surface of the decorative panel 100. The front surface of the transparent resin layer 101 is a smooth surface. The back surface of the transparent resin layer 101 has a contour corresponding to an uneven surface of the light-transmissive substrate 103. For example, the transparent resin layer 101 is formed to have a smooth front surface and an uneven back surface by filling the front surface of the binder layer 102, which has a contour corresponding to the uneven surface of the light-transmissive substrate 103, with a flowable resin (e.g., molding resins for liquid injection molding (LIM), molten resins, and the like) through insert molding using a transparent resin material.

The binder layer 102 is disposed on the front surface of the light-transmissive substrate 103, in other words, between the light-transmissive substrate 103 and the transparent resin layer 101. The binder layer 102 has a contour corresponding to the uneven surface of the light-transmissive substrate 103. The binder layer 102 is light-transmissive. The binder layer 102 may also be light-diffusive. In the case where the binder layer 102 is light-diffusive, light that enters from the front side of the decorative panel 100 is diffused so that the light is reflected across a wide range of the light-transmissive substrate 103, thereby enhancing the visibility of a three-dimensional pattern 103A created by the uneven surface of the light-transmissive substrate 103. For example, the binder layer 102 is formed by printing light-transmissive ink or ink having both light-transmissive and light-diffusive properties on the front surface of the light-transmissive substrate 103. The binder layer 102 is formed to have a contour corresponding to the uneven surface of the light-transmissive substrate 103 by compression molding or heat press molding integrally with the light-transmissive substrate 103 or by an insert molding die for forming the transparent resin layer 101.

The light-transmissive substrate 103 is a sheet-like member made of a light-transmissive resin. The light-transmissive substrate 103 has the uneven surface that creates the three-dimensional pattern 103A. The three-dimensional pattern 103A may represent unevenness of, for example, a grain pattern or a metal pattern. Thus, the three-dimensional pattern 103A created by the uneven surface of the light-transmissive substrate 103 is visible from the front surface side of the decorative panel 100 through the binder layer 102 and the transparent resin layer 101. Specifically, since the light-transmissive substrate 103 has the uneven surface, a three-dimensional pattern portion 103B that varies in height (i.e., depth) in the uneven surface is visible from the front surface side of the decorative panel 100 as a contour line of the three-dimensional pattern 103A. For example, the light-transmissive substrate 103 is formed by subjecting a sheet-shaped resin material having light transmissivity to thermal molding, such as the three dimension overlay method (TOM) molding, or to vacuum forming, thereby creating the uneven surface that creates the three-dimensional pattern 103A. In other words, in the present embodiment, unlike decorative patterns formed by conventional planar printing, the decorative pattern of the three-dimensional pattern 103A is perceptible in three dimensions when viewed from the front side of the decorative panel 100. This is due to the combined effects of decorative reflection and shape-based reflection generated by the three-dimensional pattern portion 103B, which has a three-dimensionally uneven surface.

The semi-transmissive layer 104 is superposed on the back surface of the light-transmissive substrate 103. In particular, the semi-transmissive layer 104 is configured to have a uniform transmittance and a uniform film thickness over the entire back surface of the light-transmissive substrate 103. The semi-transmissive layer 104 has semi-transmissivity. Thus, the semi-transmissive layer 104 prevents the transmissive portion 105A of the light-shielding layer 105 from being visible from the front side of the decorative panel 100 when light is not emitted from the light source 106 disposed on the back side of the light-shielding layer 105, and allows the light transmitted through the transmissive portion 105A of the light-shielding layer 105, namely a graphic symbol 100A, to be visible from the front side of the decorative panel 100 when light is emitted from the light source 106 disposed on the back side of the light-shielding layer 105. For example, the semi-transmissive layer 104 is formed by printing smoke ink having a semi-transmissive property on the back surface of the light-transmissive substrate 103. The semi-transmissive layer 104 is thermally molded or compression-molded integrally with the light-transmissive substrate 103 to have a contour corresponding to the uneven surface of the light-transmissive substrate 103.

The light-shielding layer 105 is disposed superposed on the back surface of the semi-transmissive layer 104. In other words, the light-shielding layer 105 is disposed as the outermost layer that constitutes the back surface of the decorative panel 100. For example, the light-shielding layer 105 is formed by printing a light-shielding black ink on the back surface of the semi-transmissive layer 104. The light-shielding layer 105 is thermoformed or compressed integrally with the light-transmissive substrate 103 and the semi-transmissive layer 104 to have a contour corresponding to the uneven surface of the light-transmissive substrate 103. The light-shielding layer 105 shields light from the back side of the light-shielding layer 105, thereby making various components (not illustrated) disposed on the back side of the decorative panel 100 less visible when the decorative panel 100 is viewed from the front surface side. The light-shielding layer 105 has a transmissive portion 105A along the outer frame of the graphic symbol 100A. Thus, the light-shielding layer 105 allows the graphic symbol 100A to be visible from the front side of the decorative panel 100 when the back side of the decorative panel 100 is irradiated with light.

The light source 106 is disposed on the back side of the light-shielding layer 105, at a position spaced from the light-shielding layer 105 by a predetermined distance. The light source 106 can emit light toward the back surface of the light-shielding layer 105. For example, an LED is used as the light source 106.

In the decorative panel 100 configured as described above, as illustrated in FIG. 2A, when light is not emitted from the light source 106 disposed on the back side of the light-shielding layer 105, the light incident from the front side of the decorative panel 100 is reflected on the front surface of the light transmissive substrate 103, so that the three-dimensional pattern 103A, which utilizes the height difference of the light transmissive substrate 103, is visible from the front side of the decorative panel 100. At this time, the semi-transmissive layer 104 of the decorative panel 100 makes the external shape of the transmissive portion 105A of the light-shielding layer 105 invisible from the front side of the decorative panel 100.

On the other hand, in the decorative panel 100, as illustrated in FIG. 2B, when light is emitted from the light source 106 disposed on the back side of the light-shielding layer 105, the light passes through the transmissive portion 105A of the light-shielding layer 105, the semi-transmissive layer 104, the light transmissive substrate 103, the binder layer 102, and the transparent resin layer 101, and is emitted from the front surface of the transparent resin layer 101, whereby the graphic symbol 100A formed by the transmitted light becomes visible from the front side of the decorative panel 100.

In the decorative panel 100 according to the embodiment, the semi-transmissive layer 104 has a contour corresponding to the uneven surface of the light-transmissive substrate 103.

Thus, in the decorative panel 100 according to the embodiment, the three-dimensional pattern 103A is visible from the front side of the decorative panel 100 due to the uneven surface of the light-transmissive substrate 103. At the same time, by employing the semi-transmissive layer 104 with a uniform film thickness, uneven illumination of the graphic symbol 100A, otherwise caused by variations in the film thickness of the semi-transmissive layer 104, can be effectively suppressed.

The decorative panel 100 according to the embodiment is provided with the light-shielding layer 105 disposed on the back surface of the semi-transmissive layer 104, having a contour corresponding to the uneven surface of the light-transmissive substrate 103, and having the transmissive portion 105A along the outer frame of the graphic symbol 100A.

Thus, by irradiating the back side of the decorative panel 100 according to the embodiment with light and allowing the light to pass through the decorative panel 100, the graphic symbol 100A whose uneven illumination is suppressed can be displayed on the front surface of the decorative panel 100.

The decorative panel 100 according to the embodiment is provided with the light source 106 disposed on the back side of the light-shielding layer 105, and when light emitted from the light source 106 passes through the transmissive portion 105A of the light-shielding layer 105, the semi-transmissive layer 104, and the light-transmissive substrate 103, the graphic symbol 100A is displayed on the front surface of the transparent resin layer 101, which serves as the outermost layer of the decorative panel 100.

Thus, the decorative panel 100 according to the embodiment can switch between display and non-display of the graphic symbol 100A in which uneven illumination is suppressed on the front surface of the transparent resin layer 101, while the three-dimensional pattern 103A remains visible, by turning the light source 106 on or off.

In the decorative panel 100 according to the embodiment, the semi-transmissive layer 104 has a uniform transmittance and a uniform film thickness, and is superposed on the back surface of the light-transmissive substrate 103.

Thus, the decorative panel 100 according to the embodiment can suppress uneven illumination of the graphic symbol 100A due to non-uniform transmittance or film thickness of the semi-transmissive layer 104.

### Example of Procedure of Method of Manufacturing Decorative Panel 100

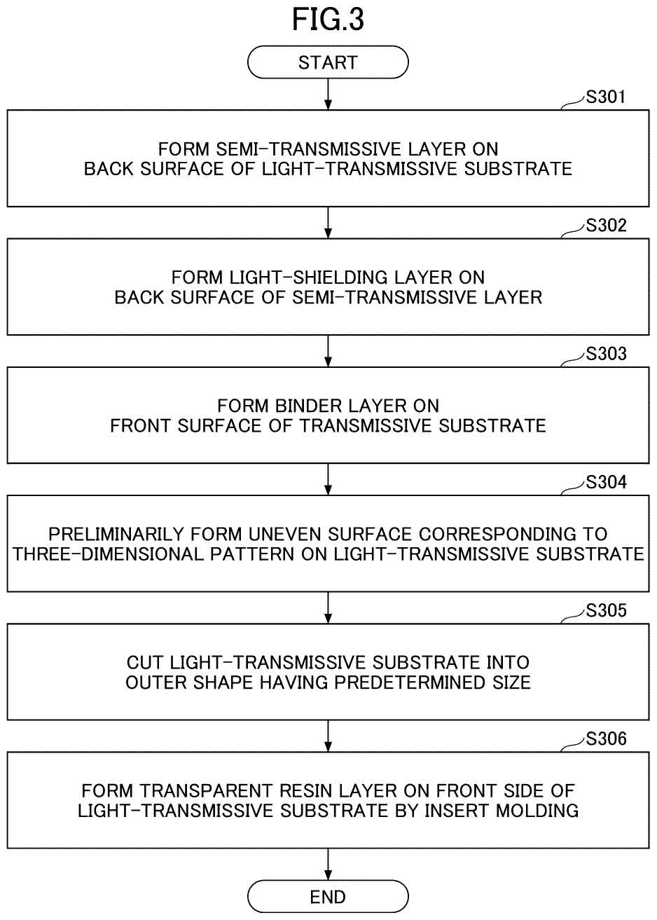

FIG. 3 is a flowchart illustrating an example of a procedure of a method of manufacturing the decorative panel 100 according to the embodiment.

First, the semi-transmissive layer 104 having a uniform transmittance and a uniform film thickness is formed by screen-printing a semi-transmissive smoke ink on the back surface of the light-transmissive substrate 103 (step S301, the semi-transmissive layer forming step).

Next, the light-shielding layer 105 having a uniform film thickness is formed by screen-printing a light-shielding black ink on the back surface of the semi-transmissive layer 104 formed in step S301 (step S302, the light-shielding layer forming step).

Next, the binder layer 102 having a uniform film thickness is formed by screen-printing a light-transmissive and light-diffusing ink on the front surface of the light-transmissive substrate 103 (step S303, the binder layer forming step).

Next, an uneven surface corresponding to the three-dimensional pattern 103A is preliminarily formed on the light-transmissive substrate 103 on which the semi-transmissive layer 104, the light-shielding layer 105, and the binder layer 102 are formed, by pneumatic molding or thermal molding (step S304, the preliminary uneven surface forming step). The preliminary uneven surface forming step in step S304 may be omitted.

Next, the light-transmissive substrate 103 on which the uneven surface is formed in step S304 is cut into an outer shape having a predetermined size by a press machine or a laser (step S305, the outline cutting step).

Next, the transparent resin layer 101 is formed by insert molding on the front surface side of the light-transmissive substrate 103 whose outer shape was cut in step S305, and an uneven surface corresponding to the three-dimensional pattern 103A is formed on the light-transmissive substrate 103 (step S306, the insert molding step). Specifically, the light-transmissive substrate 103 is set in a mold, and a molten resin is poured into the mold to form the transparent resin layer 101 on the front surface of the light-transmissive substrate 103.

In the method of manufacturing the decorative panel 100 according to the embodiment, the decorative panel 100 including the transparent resin layer 101, the light-transmissive substrate 103 disposed on the back side of the transparent resin layer 101 and expressing a three-dimensional pattern by the uneven surface of the light-transmissive substrate 103, and the semi-transmissive layer 104 disposed on the back side of the light-transmissive substrate 103 and having a contour corresponding to the uneven surface of the light-transmissive substrate 103 can be manufactured by the above procedure.

Thus, the method of manufacturing the decorative panel 100 according to the embodiment can manufacture the decorative panel 100 according to the embodiment in which the three-dimensional pattern 103A is visible from the front side and the uneven illumination of the graphic symbol 100A can be suppressed.

In the procedure of the above manufacturing method, a transparent layer may be formed between the semi-transmissive layer 104 and the light-shielding layer 105 (the transparent layer forming step). In laser processing, which is described later, this transparent layer protects the semi-transmissive layer 104 from the influence of a laser, and only the light-shielding layer 105 can be removed.

In the procedure of the above-described manufacturing method, the graphic symbol 100A is formed, for example, by forming the transmissive portion 105A along the outer frame of the graphic symbol 100A on the light-shielding layer 105 by laser processing such as an IR laser (the graphic symbol forming step).

In the decorative panel 100 manufactured by the procedure of the above-described manufacturing method, when illumination unevenness is visually perceived, the illumination unevenness may be eliminated by forming minute coating film removing portions each having a diameter of 25 μm or the like on the semi-transmissive layer 104 by laser processing, such as an IR laser (the illumination unevenness eliminating step).

### Comparative Example

Hereinafter, a comparative example of the decorative panel 100 according to the embodiment will be described with reference to FIGS. 4 through 6.

### Configuration of Conventional Decorative Sheet 10

FIG. 4 is a diagram schematically illustrating a laminate structure of a conventional decorative sheet 10. As illustrated in FIG. 4, the conventional decorative sheet 10 includes a light-transmissive substrate 11, light-reflective projecting portions 12, a semi-transmissive layer 13, and a light-shielding layer 14 in this order from the front side (upper side in the drawing).

As illustrated in FIG. 4, the conventional decorative sheet 10 includes the light-reflective projecting portions 12 corresponding to a three-dimensional pattern, on the back surface of the light-transmissive substrate 11, so that a three-dimensional pattern 12A is visual from the front side of the decorative sheet 10.

However, in the conventional decorative sheet 10, the thickness of the semi-transmissive layer 13 is different between the region having the light-reflective projecting portions 12 and the region not having the light-reflective projecting portions 12.

Therefore, in the conventional decorative sheet 10, in the case where both the region having the light-reflective projecting portions 12 and the region not having the light-reflective projecting portions 12 are included in the region overlapping a transmissive portion 14A of the light-shielding layer 14, as illustrated in FIG. 4, when the back side of the decorative sheet 10 is irradiated with light, uneven illumination of a graphic symbol 10A may occur due to the variations in the thickness of the semi-transmissive layer 13.

### Display Example of Three-dimensional Pattern 12A and Graphic Symbol 10A on Conventional Decorative Sheet 10

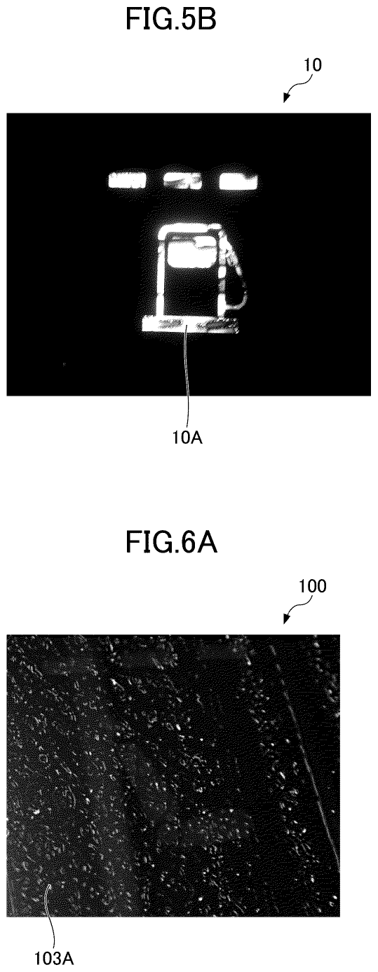

FIGS. 5A and 5B are view illustrating a display example of the three-dimensional pattern 12A and the graphic symbol 10A on the conventional decorative sheet 10.

As illustrated in FIG. 5A, in the conventional decorative sheet 10, when the back side of the decorative sheet 10 is not irradiated with light, the three-dimensional pattern 12A is visible from the front side of the decorative sheet 10. At this time, since the conventional decorative sheet 10 has the semi-transmissive layer 13, the transmissive portion 14A of the light-shielding layer 14 is less visible from the front side of the decorative sheet 10.

In addition, as illustrated in FIG. 5B, in the conventional decorative sheet 10, when the back side of the decorative sheet 10 is irradiated with light, the graphic symbol 10A formed by the light transmitted through the transmissive portion 14A of the light-shielding layer 14 can be displayed on the front surface of the decorative sheet 10.

Here, since the conventional decorative sheet 10 includes both a region having the light-reflective projecting portions 12 and a region not having the light-reflective projecting portions 12 in a region overlapping with the transmissive portion 14A of the light-shielding layer 14, as illustrated in FIG. 5B, uneven illumination of the graphic symbol 10A occurs due to the variations in the thickness of the semi-transmissive layer 13.

### Display Example of Three-dimensional Pattern 103A and Graphic Symbol 100A on Decorative Panel 100 according to Embodiment

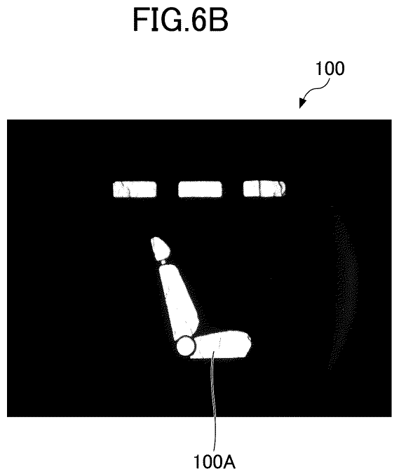

FIGS. 6A and 6B are views illustrating a display example of the three-dimensional pattern 103A and the graphic symbol 100A on the decorative panel 100 according to the embodiment.

As illustrated in FIG. 6A, in the decorative panel 100 according to the embodiment, when the back side of the decorative panel 100 is not irradiated with light, the three-dimensional pattern 103A is visible from the front side of the decorative panel 100. At this time, since the decorative panel 100 according to the embodiment has the semi-transmissive layer 104, the transmissive portion 105A of the light-shielding layer 105 is less visible from the front side of the decorative panel 100.

In addition, as illustrated in FIG. 6B, in the decorative panel 100 according to the embodiment, when the back side of the decorative panel 100 is irradiated with light, the graphic symbol 100A formed by the light transmitted through the transmissive portion 105A of the light-shielding layer 105 can be displayed on the front surface of the decorative panel 100.

In the decorative panel 100 according to the embodiment, because the transmittance and the film thickness of the semi-transmissive layer 104 are uniform, uneven illumination of the graphic symbol 100A due to variations in the thickness of the semi-transmissive layer 104 does not occur.

Although the embodiment of the present invention has been described in detail above, the present invention is not limited to these embodiments, and various alterations or modifications may be made within the scope of the present invention described in the appended claims.

For example, in the decorative panel 100 according to the embodiment, the light-shielding layer 105 is not limited to the one having the transmissive portion 105A along the outer frame of the graphic symbol, and may have the transmissive portion 105A along the outer frame of the display area of the display.

What is claimed is:

1. A decorative panel, comprising:
a transparent resin layer;
a light-transmissive substrate configured to be disposed on a back side of the transparent resin layer and configured to visually express a three-dimensional pattern created by an uneven surface of the light-transmissive substrate; and
a semi-transmissive layer configured to be disposed on a back side of the light-transmissive substrate and having a contour corresponding to the uneven surface of the light-transmissive substrate.

2. The decorative panel according to claim 1, further comprising:
a light-shielding layer configured to be disposed on a back side of the semi-transmissive layer, having a contour corresponding to the uneven surface of the light-transmissive substrate, and having a transmissive portion along an outer frame of a graphic symbol or a display area of a display.

3. The decorative panel according to claim 2, further comprising:
a light source disposed on a back side of the light-shielding layer, wherein
light emitted from the light source passes through the transmissive portion of the light-shielding layer, the semi-transmissive layer, and the light-transmissive substrate to display the graphic symbol or the display area of the display on a front surface of the transparent resin layer.

4. The decorative panel according to claim 1, wherein
the semi-transmissive layer has a uniform transmittance and a uniform film thickness, and is superposed on the back surface of the light-transmissive substrate.

5. A manufacturing method, comprising:
forming a semi-transmissive layer having a uniform transmittance and a uniform film thickness by screen-printing a semi-transmissive ink on a back side of the light-transmissive substrate;
forming, on the light-transmissive substrate on which the semi-transmissive layer is formed, an uneven surface that is perceived as a three-dimensional pattern; and
performing insert molding to form a transparent resin layer on a front surface of the light-transmissive substrate on which the uneven surface is formed.
